(19) United States
(12) Patent Application Publication
(10) Pub. No.: US 2026/0098922 A1
(43) Pub. Date: Apr. 9, 2026

(54) INTERVENTIONAL INSIDE-OUT MRI

(71) Applicant: Irving N. WEINBERG, Chevy Chase, MD (US)

(72) Inventor: Irving N. WEINBERG, Chevy Chase, MD (US)

(21) Appl. No.: 19/353,080

(22) Filed: Oct. 8, 2025

Related U.S. Application Data
(60) Provisional application No. 63/704,758, filed on Oct. 8, 2024.

(51) Int. Cl. G01R 33/383; G01R 33/00; G01R 33/381

(52) U.S. Cl. CPC G01R 33/383; G01R 33/0005; G01R 33/0047; G01R 33/381

(57) ABSTRACT

An apparatus and method for high spatial resolution MRI containing both a magnet, acting to create a magnetic field in bodily tissues near the apparatus, and a sensor, sensing electromagnetic energy emitted by bodily tissues near the apparatus, the magnet and sensor having been inserted into bodily tissues.

### CROSS-REFERENCE AND PRIORITY CLAIM

This application claims priority to United States Provisional Patent Application Ser. No. 63/704,758, entitled “INTERVENTIONAL INSIDE-OUT MRI” filed Oct. 8, 2024, the entirety of which is incorporated by reference.

### FIELD

An apparatus and method for high-resolution images of tissues within a body.

### BACKGROUND

Inside-out borehole nuclear magnetic resonance (NMR) systems have been used in the oil exploration field since 1960, as taught by R. J. S. Brown and B. W. Gamson in the Transactions of the AIME, entitled “Nuclear magnetism logging”. That 1960 article described an electromagnet being lowered into a well to establish a static magnetic field, which was used to assay the signal amplitude decay rates of various materials. In 1980, J. A. Jackson, L. J. Burnett, J. F. Harmon taught that a permanent magnet could be inserted into the borehole to establish a static magnetic field, described in the article entitled “Remote (Inside-Out) NMR. III. Detection of Nuclear Magnetic Resonance in a Remotely Produced Region of Homogeneous Magnetic Field.”

Intravascular magnetic resonance imaging (MRI) has been taught by G. C. Hurst et al, in the 1992 Magnetic Resonance in Medicine entitled “Intravascular (Catheter) NMR Receiver Probe: Preliminary Design Analysis and Application to Canine Iliofemoral Imaging”. In this and similar articles, the static field is established by magnets that surround the body of a subject. The intravascular probe contains a radiofrequency receiver coil. The coil is highly sensitive to radiation in its vicinity, which effectively increases the signal from tissues surrounding the probe and yields high resolution images.

### SUMMARY

Disclosed embodiments describe an apparatus and method for high spatial resolution MRI containing both a magnet, acting to create a magnetic field in bodily tissues near the apparatus, and a sensor, sensing electromagnetic energy emitted by bodily tissues near the apparatus, the magnet and sensor having been inserted into bodily tissues.

### BRIEF DESCRIPTION OF THE FIGURES

FIG. 1 shows an embodiment of the apparatus according to the disclosed embodiments; and

FIG. 2 shows flowchart of a method for obtaining high resolution magnetic resonance images of tissue.

### DETAILED DESCRIPTION

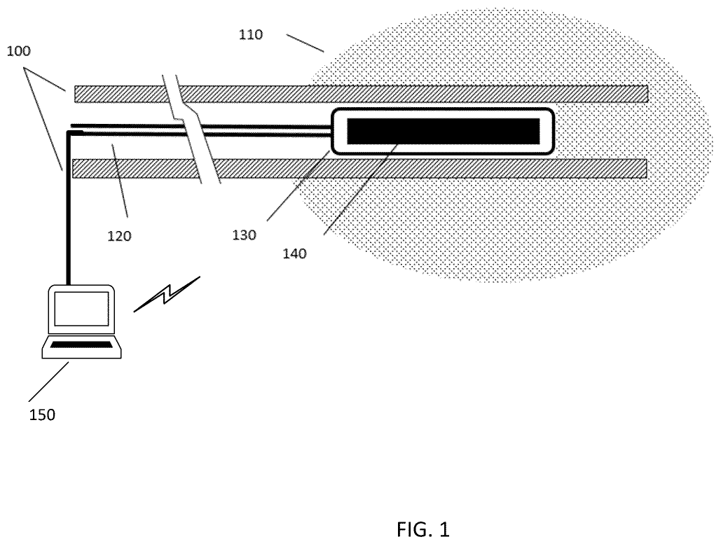

As shown in FIG. 1, an apparatus may include at least one magnet 140 and at least one sensor 130, which are in the vicinity of one another, within a body part of a human or non-human animal. One or more controllers 150 may be in communication with the magnet 140 and/or sensor 130, configured to control the at least one magnet and/or the at least one sensor. The magnet 140 creates a magnetic field in bodily tissues 110 near the apparatus. The at least one sensor 130 is sensitive to electromagnetic energy emitted by bodily tissues 110 in the vicinity of the apparatus. The magnet 140 and sensor 130 are configured to be inserted into the bodily tissues 11 prior to operation. In some embodiments, the at least one magnet and the at least one sensor are inserted via at least one catheter 100.

For the purposes of this disclosure, catheter 100 may be any device that can be used to introduce materials into tissues 110, for example a trocar or plastic tube or hollow needle. It is understood that that the magnet 140 and sensor 130 may be introduced into tissues without the need of a catheter, for example by pushing magnet 140 and sensor 130 into a body part. In some embodiments magnet 140 and sensor 130 may be coupled to one another. In some embodiments, magnet and sensor may be affixed to one another or tethered to one another. In some embodiments magnet and sensor may be inserted independent of each other and still in the vicinity of each other. In some embodiments, magnet 140 and sensor 130 may be ingested, or may be inserted into a natural orifice (for example, as a tampon to examine uterine tissues).

In some embodiments, the catheter 100 or other means may also be configured to introduce materials into tissues 110 in the body of a living animal (for example, a human person or a horse). The materials may contain one or more wires 120 that connect to one or more sensors 130 sensitive to electromagnetic radiation. The sensor(s) 130 are in the vicinity of the magnet 140 that is also within tissues 110.

For the purposes of this disclosure, the term “magnet” is defined as a device that can create a magnetic field. In some embodiments, the magnetic field magnitude has an average value of at least one milli Tesla over an area no less than 100 microns from the magnet. Magnet 140 may be a permanent magnet or may be an electromagnet or may be an electropermanent magnet or may be a combination of one or more of these types of magnets. An electropermanent magnet is defined as a coil surrounding a material that retains magnetization after a current has passed through the coil. It is understood that the magnet may have a shape or configuration that is suitable for creating a magnetic field suitable for imaging, for example as known in the field of oil exploration. In some embodiments, magnet 140 may be a magnetizable material that is magnetized by a magnet or coil outside the body part. In some embodiments, the field of view of the apparatus is on one side of the apparatus. In some embodiments, the field of view of the apparatus is on all sides of the apparatus.

In some embodiments, the term “vicinity of the magnet” is defined as within a distance of no more than one centimeter from the magnet. In an embodiment, “vicinity of the magnet” is defined as within a distance of no more than 100 microns from the magnet. In an embodiment, “vicinity of the magnet” is defined as within a distance of no more than 100 millimeters from the magnet. In an embodiment, “vicinity of the magnet” is defined as within a distance of no more than 2 centimeters from the magnet.

In some embodiments, the magnet and sensor are less than 3 mm in combined diameter, or less than 2 mm in combined diameter, or less than 1 mm in combined diameter, so as to be insertable into tissues with minimal damage.

In some embodiments, sensor 130 may be one or more radiofrequency coils. It is understood that sensor 130 may be one of many types of magnetometers, for example a quantum sensing device such as a diamond with nitrogen vacancies. It is understood that sensor 130 may include electronic parts required to be sensitive to magnetic fields, for example sensor 130 may include a preamplifier or power source.

In some embodiments, wires 120 may convey current or other electrical signals from sensor 130. In an embodiment, wire 120 may be used as a guide wire or pusher to transport magnet 140 and/or sensor 130 within catheter 100. In some embodiments, sensor 130 and/or magnet may communicate to at least one controller 150, such as a computer, outside the tissues wirelessly.

In some embodiments, magnet 140 and sensor 130 are made of biocompatible materials that do not generally cause adverse reactions in a body. In some embodiments, magnet 140 and sensor 130 are coated with a biocompatible material that does not generally cause adverse reactions in a body.

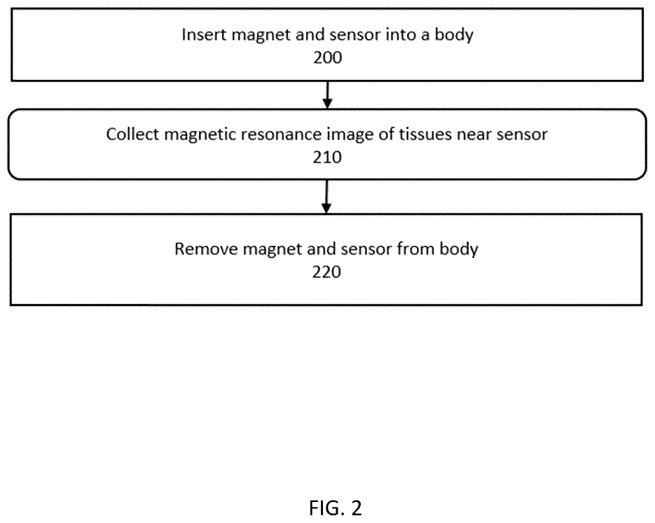

Referring to FIG. 2, in a method for obtaining high resolution magnetic resonance images of tissue, a magnet and sensor are introduced into tissues of a living body 200. It is understood that, for example, magnet 140 and sensor 130 may be introduced at different times into the tissues. A pulse sequence is executed involving the sensor that results in collection of a magnetic resonance image of tissues in the vicinity of the body part 210. In order to collect such an image, magnetic gradient fields may be present. The magnetic gradient fields may be produced by the magnet, and the image may be computed using methods described for MRI with a “built-in gradient.” One example of such a method was taught by G. E. Sarty and L. Vidarsson in the 2018 Magnetic Resonance Imaging article entitled “Magnetic resonance imaging with RF encoding on curved natural slices”. In some embodiments, the magnet may include coils capable of generating time-dependent gradients. Controller may control operations of the magnet and sensor to collect the magnetic resonance image. The magnet and sensor are removed from the tissues body 220. It is understood that the magnet and sensor may remain in the body for extended periods of time or indefinitely, for example to repeatedly sample the status of tissues in a body. An extended period may be an hour, or a day, or a month, or a year, or for the life of the body.

For the purposes of this disclosure, it is understood that the term “introduced into tissues” may include the process of inserting a catheter into a body and then inserting the magnet and sensor into the catheter or may include other processes of delivering payloads into tissues. An example of such a process would be the insertion of a catheter or introducer at a location remote to the tissues (e.g., into a femoral artery) and then the guidance of a catheter via a wire into the desired tissues (for example a section of the aorta). Said processes are known in the field of interventional radiology.

For the purposes of this disclosure, “high resolution” means that the pixel size of images generated by the apparatus have at least one dimension smaller than one centimeter, or one millimeter, or 100 microns, or 10 microns, or one micron. It is understood that the increased signal obtained by the apparatus may be used to derive information about the tissue that may be distinct from high resolution, for example the signal may provide information about the biochemical status or constituents of the nearby tissues, for example by spectroscopy. It is understood that in the practice of MRI, signal strength and spatial resolution are related quantities, since the higher the signal-to-noise ratio, the more information content per voxel and therefore the smaller the pixels can be. In the disclosed embodiments, high signal strength is obtained by having the RF receiver be very close to the region of interest for imaging.

It is understood that the apparatus may be operated by a user within a magnetic field created by a magnet external to the body, or in conjunction with images obtained using x-rays or ultrasound or other imaging techniques. For example, the catheter may be inserted into a femoral artery and guided to the aorta using an x-ray C-arm. It is understood that such use may result in providing such a C-arm suite with MRI compatibility.

In some embodiments, magnet 140 may be used to propel magnetizable tools or particles, and to print tissues within a body.

In some embodiments, magnet 140 may be segmented so that the apparatus may be flexibly inserted into tissues by allowing bending of magnet 140.

Those skilled in the art will recognize, upon consideration of the above teachings, that the above exemplary embodiments and the controller may be based upon use of one or more programmed processors programmed with a suitable computer program. However, the disclosed embodiments could be implemented using hardware component equivalents such as special purpose hardware and/or dedicated processors. Similarly, general purpose computers, microprocessor-based computers, micro-controllers, optical computers, analog computers, dedicated processors, application specific circuits and/or dedicated hard wired logic may be used to construct alternative equivalent embodiments.

Moreover, it should be understood that control and cooperation of the above-described components may be provided using software instructions that may be stored in a tangible, non-transitory storage device such as a non-transitory computer readable storage device storing instructions which, when executed on one or more programmed processors, carry out the above-described method operations and resulting functionality. In this case, the term “non-transitory” is intended to preclude transmitted signals and propagating waves, but not storage devices that are erasable or dependent upon power sources to retain information.

Those skilled in the art will appreciate, upon consideration of the above teachings, that the program operations and processes and associated data used to implement certain of the embodiments described above can be implemented using disc storage as well as other forms of storage devices including, but not limited to non-transitory storage media (where non-transitory is intended only to preclude propagating signals and not signals which are transitory in that they are erased by removal of power or explicit acts of erasure) such as for example Read Only Memory (ROM) devices, Random Access Memory (RAM) devices, network memory devices, optical storage elements, magnetic storage elements, magneto-optical storage elements, flash memory, core memory and/or other equivalent volatile and non-volatile storage technologies without departing from certain embodiments. Such alternative storage devices should be considered equivalents.

While various exemplary embodiments have been described above, it should be understood that they have been presented by way of example only, and not limitation. Thus, the breadth and scope of the present invention should not be limited by any of the above-described exemplary embodiments, but should instead be defined only in accordance with the following claims and their equivalents.

1. An apparatus for collecting a high resolution magnetic resonance image of tissues of a living body, the apparatus comprising:
at least one magnet, the magnet creating a magnetic field in bodily tissues in the vicinity of the magnet,
at least one sensor, the sensor being sensitive to electromagnetic energy emitted by bodily tissues in the vicinity of the magnet, and
at least one controller configured to control the at least one magnet and at least one sensor to collect a high resolution magnetic resonance image of the tissues via the at least one sensor which is sensitive to electromagnetic energy emitted by the tissues in the vicinity of the at least one magnet.

2. The apparatus of claim 1, further comprising a catheter or other hollow instrument for inserting the at least one magnet and at least one sensor into the bodily tissues via.

3. The apparatus of claim 1, wherein the sensor contains at least one coil sensitive to radiofrequency energy emitted by tissues in a magnetic field generated by the magnet.

4. The apparatus of claim 1, wherein the at least one magnet is a permanent magnet.

5. The apparatus of claim 1, wherein the at least one magnet is an electropermanent magnet.

6. The apparatus of claim 1, wherein the magnet and sensor have a combined diameter of less than 3 millimeters in diameter.

7. The apparatus of claim 1, wherein the magnet and sensor have a combined diameter of less than 2 millimeters.

8. The apparatus of claim 1, wherein the magnet and sensor are less than 1 millimeter in diameter.

9. The apparatus of claim 1, wherein the magnet and sensor are coated with a biocompatible material.

10. The apparatus of claim 1, wherein the magnet is segmented to allow flexible entry into a body.

11. A method for obtaining high resolution magnetic resonance images of tissue of a living body comprising:
inserting at least one magnet and at least one sensor into the tissues, and
collecting a high resolution magnetic resonance image of the tissues via the at least one sensor which is sensitive to electromagnetic energy emitted by the tissues in the vicinity of the at least one magnet.

12. The method of claim 11, wherein the at least one magnet and at least one sensor are introduced into the tissue via a catheter.

13. The method of claim 11, further comprising removing the at least one magnet and at least one sensor from the tissue after obtaining magnetic resonance images.

14. The method of claim 11, wherein the at least one magnet and at least one sensor remain in the tissue for an extended period.

15. The method of claim 11, wherein the magnetic resonance images are obtained using the built-in gradient of the magnet.

16. The method of claim 11, wherein the at least one magnet and at least one sensor are introduced into the tissue via ingestion.

17. The method of claim 11, wherein the at least one magnet and at least one sensor are introduced into the tissue via a natural orifice.
